(19) United States
(12) Patent Application Publication
(10) Pub. No.: US 2014/0205854 A1
(43) Pub. Date: Jul. 24, 2014

(54) CIRCUIT BOARD MATERIAL

(71) Applicant: Ohmega Technologies, Inc., Culver City, CA (US)

(72) Inventors: Daniel BRANDLER, Moorpark, CA (US); Bruce MAHLER, Thousand Oaks, CA (US)

(73) Assignee: Ohmega Technologies, Inc., Culver City, CA (US)

(21) Appl. No.: 14/158,069

(22) Filed: Jan. 17, 2014

Related U.S. Application Data
(60) Provisional application No. 61/754,156, filed on Jan. 18, 2013.

(51) Int. Cl. H05K 1/03; H05K 3/06

(52) U.S. Cl. CPC H05K 1/03; H05K 3/067
USPC 428/626; 205/176; 420/591; 156/150

(57) ABSTRACT

A circuit board material includes an electrical resistance material layer having a preselected resistivity adhered to the support layer, and a barrier layer adhered to the electrical resistive layer, and a conductive layer adhered to the barrier layer, wherein the barrier layer is plated on the conductive material such that the resistance of the subsequently applied resistive layer does not vary substantially during exposure to printed circuit board processing chemistries. The process for making the material is directed to adjusting the electro deposition of the barrier layer by using the time for etching the resistive layer of the circuit board material in a standard etching bath.

### CROSS REFERENCE TO RELATED APPLICATIONS

This application claims the benefit of U.S. Provisional Application No. 61/754,156, filed Jan. 18, 2013, which is herein incorporated by reference in its entirety.

### FIELD OF THE INVENTION

The present invention relates to an improved circuit board material, and more particularly to a circuit board material having a resistance material layer that may be processed under typical printed circuit board processing conditions without having the resistivity of the resistive material layer substantially adversely impacted.

### BACKGROUND OF THE INVENTION

One of the trends in the electronics industry is to narrow the width of resistors in printed circuit board materials. The required resistor percent tolerance in ohms often drives the minimum resistor size. The advent of HDI fine line technologies and LDI laser direct imaging has enabled greater precision and tighter tolerances on the conductor widths and resistor dimensions. The challenge was then to create resistive elements having a narrow width, e.g., less than 125 uM in width with the required tolerance in ohmic value.

One problem in doing so is that during the processing of printed circuit board materials, the resistive elements of the circuit board material are exposed to a variety of chemical processes including alkaline copper etchants, alkaline oxidizing sodium hydroxide and sodium chlorite solutions and more recently acidic oxidizing solutions. The exposure of the resistive elements to the acidic oxidizing solutions substantially changes the resistivity of the resistive elements, typically raising the ohmic value of the resistors, i.e., shifting upward the sheet resistivity of the resistive elements. Furthermore, as the resistor size diminished, the effect of that exposure has increased to the point that miniature resistors may not meet the required ohmic percent tolerance. This often required artwork adjustments to compensate for the change in resistivity to maintain the required resistor percent tolerance in ohms.

Typical etchants operate at 124-126° F. at a pH of 7.6-8.4 with a 4.0 to 5.0 molar chloride concentration and a copper concentration of 10-20 oz/gallon.

An example of an acidic oxidizing solution is as follows:
Sodium Persulfate: 150 gr/l+/−10%
Sulfuric Acid: 20 ml/l+/−10%
Temperature: 40° C.+/−2°

Nickel-phosphorus layers containing circuit board materials are disclosed in U.S. Pat. No. 4,892,776 and nickel-tin layers containing circuit board materials are disclosed in U.S. Pat. No. 5,689,227, assigned to Ohmega Technologies, Inc., the entireties of which are incorporated herein by this reference (The “Ohmega Technologies Patents”).

Accordingly, a need exists for a circuit board material comprised of resistive materials whereby during exposure of the circuit board material to typical printed circuit board processing chemistries, the resistance of the resistive material does not substantially vary.

### SUMMARY OF THE PREFERRED EMBODIMENTS

In accordance with a first aspect of the present invention there is provided a circuit board material comprising, an electrical resistance material layer having a preselected resistivity adhered to the support layer, a barrier layer adhered to the electrical resistive layer, and a conductive layer adhered to the barrier layer, wherein the barrier layer is plated on the conductive material such that the resistance of the subsequently applied resistive layer does not vary substantially during exposure to printed circuit board processing chemistries.

In accordance with another aspect of the present invention, provided is a barrier layer in a circuit board material, the circuit board material comprising a conductive substrate, the barrier layer, and a resistive material layer, wherein the barrier layer protects the sheet resistivity of the resistance material layer from appreciable change during acidic oxidizing conditions of printed circuit board processing.

In accordance with another aspect of the present invention, provided is a process for producing a circuit board material comprising a conductive layer, an electro deposited nickel-tin alloy barrier layer and a nickel-phosphorous resistive layer, the process comprising adjusting the amount of the nickel-tin electro deposition such that the resistive material is etched from the circuit board material in a one molar copper etchant solution in a time period ranging from 10-18 minutes.

The invention, together with additional features and advantages thereof, may be best understood by reference to the following description.

### BRIEF DESCRIPTION OF THE DRAWING

FIG. 1 is a cross-sectional view of a printed circuit board material showing the arrangement of a support layer, an electrical resistive layer, a barrier layer, and a conductive layer in accordance with a preferred embodiment of the present invention.

### DETAILED DESCRIPTION OF THE PREFERRED EMBODIMENTS

The following description and drawings are illustrative and are not to be construed as limiting. Numerous specific details are described to provide a thorough understanding of the disclosure. However, in certain instances, well-known or conventional details are not described in order to avoid obscuring the description. References to one or another embodiment in the present disclosure can be, but not necessarily are, references to the same embodiment; and, such references mean at least one of the embodiments.

Reference in this specification to “one embodiment” or “an embodiment” means that a particular feature, structure, or characteristic described in connection with the embodiment is included in at least one embodiment of the disclosure. Appearances of the phrase “in one embodiment” in various places in the specification do not necessarily refer to the same embodiment, nor are separate or alternative embodiments mutually exclusive of other embodiments. Moreover, various features are described which may be exhibited by some embodiments and not by others. Similarly, various requirements are described which may be requirements for some embodiments but not other embodiments.

The terms used in this specification generally have their ordinary meanings in the art, within the context of the disclosure, and in the specific context where each term is used. Certain terms that are used to describe the disclosure are discussed below, or elsewhere in the specification, to provide additional guidance to the practitioner regarding the description of the disclosure. For convenience, certain terms may be highlighted, for example using italics and/or quotation marks: The use of highlighting has no influence on the scope and meaning of a term; the scope and meaning of a term is the same, in the same context, whether or not it is highlighted. It will be appreciated that the same thing can be said in more than one way.

Consequently, alternative language and synonyms may be used for any one or more of the terms discussed herein. Nor is any special significance to be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and is not intended to further limit the scope and meaning of the disclosure or of any exemplified term. Likewise, the disclosure is not limited to various embodiments given in this specification.

Unless otherwise defined, all technical and scientific terms used herein have the same meaning as commonly understood by one of ordinary skill in the art to which this disclosure pertains. In the case of conflict, the present document, including definitions, will control.

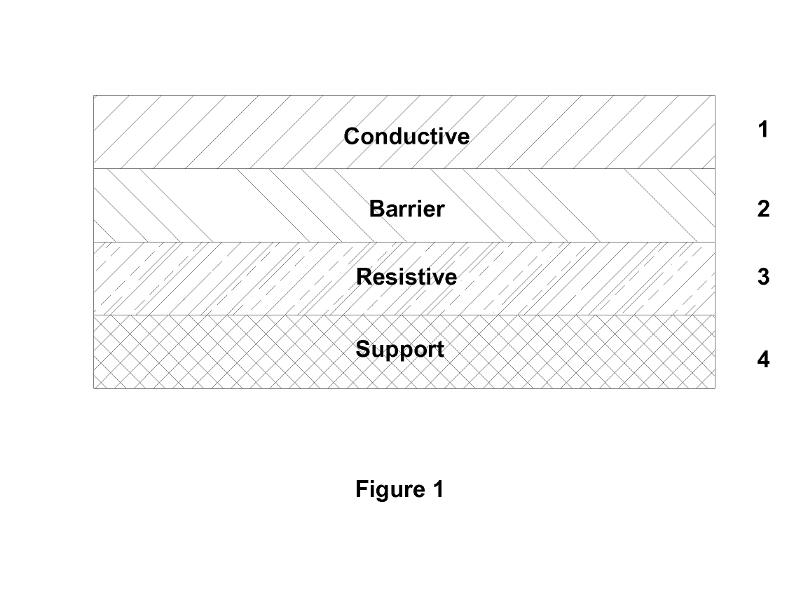

In general, and with reference to FIG. 1, a circuit board material according to the present invention includes conductive layer 1, barrier layer 2, resistive layer 3 and support layer 4.

The process for making a preferred embodiment of the present invention generally starts with selecting the conductive layer which is typically copper foil. A nickel tin barrier layer is then plated on the conductive layer in a manner that protects the next layer, a nickel phosphorus resistive layer, from appreciable change in resistivity when exposed to typical printed circuit board processing chemistries. The resistive layer is plated on the nickel tin barrier layer. The resulting structure is laminated onto a supporting substrate.

In one of the preferred embodiments of the invention, the barrier layer is plated on the conductive layer such that the resistance of the subsequently applied resistive layer does not vary substantially during exposure to typical printed circuit board processing chemistries, particularly for (although not limited to) planar resistor elements at or below about 125 uM widths.

The term “layer” is intended to comprise a single layer as well as multiple layers of the same functional material or the same material. For example, a resistance material “layer” may include multiple layers of different resistance materials or multiple layers of the same resistance material, or a single layer of a resistance material.

In general, the appropriate barrier layer is electro deposited by testing the conditions in which the conductive layer is etched during exposure of the circuit board material to typical printed circuit board processing chemistries, and then adjusting the plating of the nickel tin barrier layer so that upon exposure of the final circuit board material to typical printed circuit board processing chemistries, the resistivity of the resistance layer does not substantially change. It has been found that the time it takes to etch away the resistive material correlates with the chemical resistivity of the resistance material layer.

The electrical resistive layer can be made of a variety of materials but preferably it is a nickel-phosphorus layer made in accordance with the foregoing Ohmega Technologies Patents. A nickel-phosphorus layer electro deposited on copper foil is well known to those of skill in the art as OhmegaPly®, and is further described at www.ohmega.com, the entirety of which is incorporated by reference into this patent application. Generally the electrical resistance layer has a preselected resistivity, e.g., 10 to 250 ohms per square.

A barrier layer is adhered to the conductive material layer, wherein the barrier layer is capable of protecting the resistance material layer from attack by acidic oxidizing chemistries as well as alkaline ammonical copper etchants. Protecting is meant to include minimizing a change in the sheet resistivity of the resistance material layer during typical printed circuit board processing. Preferably, the barrier layer is a nickel-tin alloy electro-deposited in accordance with the foregoing Ohmega Technologies Patents and as discussed further below, optimally approximately 50:50 Sn to Ni atomic ratio; the equivalent weight ratio being approximately 65:35 Sn to Ni.

Preferred operating conditions for electroplating the nickel-tin layer are as follows:

| Chemical Component | M/1 | Range |
|---|---|---|
| NiCl₂ 6H₂O | 0.125 | 0.01-0.13 |
| SnCl₂ 2H2O | 0.125 | 0.01-0.14 |
| K₄P₂O₇ | 0.45 | 0.40-0.50 |
| Glycine | 0.27 | 0.24-0.30 |
| Temperature: | 50° C. | 40-60° C. |
| Current Density | 0.4 ASF | 0.1-0.6 ASF |

The temperature and current density may be varied to control the etch time and therefore the chemical resistivity of the resistance materials layer during processing of the printed circuit board material.

The nickel-tin (NiSn) deposition rate is a function of the current density in amp-minutes per square foot (ASF). The current density and the plating time (line speed) determine the amount of deposition, and hence, the barrier layer thickness. The relationship is nearly linear, meaning for a given percent increase in current or time there is a corresponding percentage increase in deposition thickness. The current density range is greater than typical because it is by varying the current density according to the etch time that the required degree of chemical resistivity is achieved.

In a preferred process for determining the ASF at a given temperature and a given line speed for the NiSn deposition, a NiSn barrier layer is applied to the conductive material layer by plating using the solution described above at an ASF within the foregoing range. Then a nickel phosphorous resistance layer is applied to the barrier layer. Then the resistance layer is laminated to a substrate, and thereafter resistor arrays are imaged on the resistive layer to provide a test circuit board material. The resistivity of the resistive layer is then measured.

The test circuit board material is then placed in an etchant solution, preferably a 1 molar copper sulfate solution at 90° C., and the test circuit board material is observed to determine how long it takes to etch off the resistive layer. The etch time is measured by direct observation of the complete removal of the resistive layer from the substrate. If the etch time is outside of the preferred range, the ASF of the nickel tin plating bath is adjusted and another sample is taken and retested. The etch time is generally from 10-18 minutes, preferably from 11-17 minutes, more preferably from 13-15 minutes and optimally at about 14 minutes. It has been found that by adjusting the ASF for the electro-deposition of the nickel tin layer to an ASF whereby the resistive layer is etched off after a period of time of 14 minutes+/−4 minutes, the resistive layer of the resulting circuit board material is substantially protected from attack by the acidic oxidizing chemistries and alkaline copper etchants employed during printed circuit board processing.

Thus, in a preferred embodiment, the ASF is adjusted until the etch time of the resistance layer is in the preferred range.

Once the test circuit board material exhibits the desired resistive etch time in the copper sulfate solution, the ASF of the nickel-tin electro deposition is set, and a material is produced having the conductive layer, the preferred barrier layer, and the resistive layer. A support layer is laminated thereon to thereby produce a circuit board material in accordance with one preferred embodiment of the present invention. The circuit board material is then ready for processing by printed circuit board manufacturers.

The circuit board material with the preferred etch time range, as manufactured, exhibits little or no change in acidified oxidizing solutions. “Little or no change” means, in general, that the resistivity does not change by more than 10%, preferably by not more than 5%, more preferably by not more than 3% and optimally by not more than 1%, over a predetermined period of dwell time in the bath, preferably after 30 seconds, more preferably after 60 seconds and optimally after 90 seconds.

The support layer can be any organic polymer dielectric substrate but typically is epoxy, polyimide, or PTFE blends.

Thus, one aspect of the present invention is the discovery that one way of measuring the degree in which the resistance layer is protected is by monitoring the etch time of the circuit board material in a standardized one molar copper sulfate etching solution at 90° C. Increasing the copper sulfate etch time means that the resistance layer is better protected from attack when exposed to printed circuit board processing chemistries.

Accordingly, the deposition of the barrier layer is not controlled by thickness, but rather the deposition of the barrier layer is controlled by chemical resistivity as measured by etch time in a standardized copper sulfate stripper solution.

The barrier layer is provided for all standard sheet resistivities, 10 to 250 ohms per square, with a single target chemical resistivity for the range of electrical sheet resistivities.

The barrier layer provides protection for micro-trace resistor element widths as low as 40 microns at sheet resistivities of 10 to 250 ohms/square. The percent change in ohmic value of these resistors after exposure to oxidizing chemistries, almost regardless as to the degree of exposure, is near zero when the barrier layer thickness is controlled by accurate measurement of the etch time in a standardized stripping solution.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” Where the context permits, words in the above Detailed Description of the Preferred Embodiments using the singular or plural number may also include the plural or singular number respectively. The word “or” in reference to a list of two or more items, covers all of the following interpretations of the word: any of the items in the list, all of the items in the list, and any combination of the items in the list.

Accordingly, although exemplary embodiments of the invention have been shown and described, it is to be understood that all the terms used herein are descriptive rather than limiting, and that many changes, modifications, and substitutions may be made by one having ordinary skill in the art without departing from the spirit and scope of the invention.

What is claimed is:

1. A circuit board material comprising an electrical resistance material layer having a preselected resistivity adhered to the support layer, a barrier layer adhered to the electrical resistive layer, and a conductive layer adhered to the barrier layer, wherein the barrier layer is plated on the conductive material such that the resistance of the subsequently applied resistive layer does not vary substantially during exposure to printed circuit board processing chemistries.

2. The circuit board material according to claim 1 wherein the application of the barrier layer is controlled by etch time in a 1 molar copper sulfate solution with an etch time ranging from 10 to 18 minutes.

3. The circuit board material according to claim 1 wherein the application of the barrier layer is controlled by etch time in a 1 molar copper sulfate solution with an etch time ranging from 11 to 17 minutes.

4. The circuit board material according to claim 1 wherein the application of the barrier layer is controlled by etch time in a 1 molar copper sulfate solution with an etch time ranging from 13 to 15 minutes.

5. The circuit board material according to claim 1 wherein the application of the barrier layer is controlled by etch time in a 1 molar copper sulfate solution with an etch time of about 14 minutes.

6. The circuit board material according to claim 1 wherein the resistance layer comprises materials with sheet resistivities ranging from 10 to 250 ohms per square.

7. The circuit board material according to claim 1 wherein the barrier layer provides protection to resistive elements ranging from 40 to 125 microns in width.

8. The circuit board material of according to claim 1 wherein the printed circuit board processing chemistries comprise acidic oxidizing solutions.

9. The circuit board material according to claim 1 wherein the resistive layer material is a nickel-phosphorous alloy.

10. The circuit board material according to claim 1 wherein the barrier layer material is a nickel-tin alloy.

11. The circuit board material according to claim 7, wherein the weight ratio of nickel to tin is about 65:35.

12. The circuit board material according to claim 1, wherein the resistivity varies no more than 10%.

13. The circuit board material according to claim 1, wherein the resistivity varies no more than 5%.

14. A barrier layer in a circuit board material, the circuit board material comprising a conductive substrate, the barrier layer, a resistive material layer and a substrate, wherein the barrier layer protects the sheet resistivity of the resistance material layer from appreciable change during acidic oxidizing conditions of printed circuit board processing.

15. A process for producing a circuit board material comprising a conductive layer, an electro deposited nickel tin alloy barrier layer and a nickel phosphorous resistive layer, the process comprising adjusting the amount of the nickel tin electro deposition such that the resistive material is etched from the circuit board material in a 1 molar copper etchant solution during a period ranging from 10-18 minutes.

16. The process according to claim 16, wherein the period ranges from 11 to 17 minutes.

17. The process according to claim 10, wherein the period ranges from 13 to 15 minutes.

18. The process according to claim 10, wherein the period is about 14 minutes.

19. The process according to claim 16 further including the steps of imaging resistors into the resistive layer, and laminating it onto a substrate.
